(19) United States
(12) Patent Application Publication
(10) Pub. No.: US 2023/0163018 A1
(43) Pub. Date: May 25, 2023

(54) SUBSTRATE HOLDING APPARATUS AND SUBSTRATE PROCESSING APPARATUS

(71) Applicant: Hitachi High-Tech Corporation, Tokyo (JP)

(72) Inventors: Yoshihiro SATOU, Tokyo (JP); Toshio MASUDA, Tokyo (JP); Akio YAZAKI, Tokyo (JP); Kenshiro OHTSUBO, Tokyo (JP); Toshinori KOBAYASHI, Tokyo (JP); Shigenori TOGASHI, Tokyo (JP)

(73) Assignee: Hitachi High-Tech Corporation, Tokyo (JP)

(21) Appl. No.: 17/920,907

(22) PCT Filed: May 25, 2020
(86) PCT No.: PCT/JP2020/020536

§ 371 Date: Oct. 24, 2022

(51) Int. Cl. H01L 21/683; H01L 21/67; H01L 21/687

(52) U.S. Cl. CPC H01L 21/6838; H01L 21/67288; H01L 21/68721

(57) ABSTRACT

The present disclosure provides a technology for holding a substrate with high precision and a high degree of flatness. A substrate holding device of the present disclosure comprises: a rotary stage; and a clamp part that supports, in a planar direction of the substrate, an edge of a substrate which is the object to be rotated by the rotary stage. The rotary stage is provided with: a plurality of gas supply openings that supply a gas toward the substrate; and one or more gas exhaust openings that are provided to each of the plurality of gas supply openings so as to surround the periphery of the gas supply opening.

### TECHNICAL FIELD

The present disclosure relates to a substrate holding apparatus and a substrate processing apparatus.

### BACKGROUND ART

In a semiconductor manufacturing process, the presence of a foreign matter on a substrate such as a semiconductor wafer causes a defect such as an insulation defect or a short circuit of wiring. These foreign matters are mixed in various states such as those generated from a movable portion such as a conveyance device, those generated from a human body, those generated by a reaction in a processing device by a process gas, and those mixed in chemicals and materials. The same applies to a process of manufacturing a magnetic disk or a liquid crystal display element, and adhesion of generated foreign matter to a substrate (magnetic disk or liquid crystal display element) causes a defect.

Therefore, by detecting and managing the foreign matters on the substrate surface using the surface inspection device in the manufacturing process, the dust generation status of each manufacturing device, the cleanliness of each process, and the like are monitored and controlled to improve the quality of the product, the yield, and the like. In the foreign matter inspection method, the substrate surface is irradiated with light such as laser light, and scattered light from the foreign matter is detected to inspect the size, the attachment position, and the like of the foreign matter, and acquire the foreign matter information as unique information. Therefore, when there is undulation or the like of the substrate surface, the angle of the scattered light varies, and the accuracy of the size and the attachment position of the foreign matter is affected, and the reliability of the foreign matter information of the substrate is lowered.

As a method of holding the substrate, which is one factor of the undulation of the substrate surface, there are roughly classified into a back surface adsorption type and a back surface non-contact type. In the back surface adsorption type, an air adsorption port is provided in a flat table to adsorb the back surface of the substrate, and the undulation of the substrate depends on the flatness of the table. On the other hand, the back surface non-contact type is a holding type in which the substrate is held in the vicinity of the outer periphery of the substrate from the outside and the substrate surface floats in the air, and an advanced mechanism is required to suppress the undulation of the substrate and secure the flatness.

As a technique related to a back surface non-contact type, PTL 1 discloses a rotating wafer chuck mechanism in which a plurality of pressurized gas elements and a plurality of vacuum elements for adsorbing out the gas are arranged on a chuck surface, a wafer is floated in the air to be held in a vertical direction, and is held in a horizontal direction at a wafer edge.

### CITATION LIST

### Patent Literature

PTL 1: JP 2017-504199 A

### SUMMARY OF INVENTION

### Technical Problem

PTL 1 has a structure that can maintain the flatness of the wafer while avoiding contact of the back surface of the wafer with the chuck surface. A gas supply unit as one pressurized gas element and gas exhaust units as a plurality of vacuum elements are arranged adjacent to each other, so that the gas from the pressurized gas element flows to the plurality of vacuum elements and is exhausted. That is, the gas supplied from the pressurized gas element is exhausted to the adjacent vacuum element. Since the wafer chuck mechanism is rotationally driven, the pressurized gas element and the vacuum element rotate in the same manner. Therefore, the gas from the pressurized gas element tends to flow outward due to the action of the centrifugal force depending on the rotational radius position. Since the wafer is held by the balance between the positive pressure and the negative pressure of the gas, the air flow distribution, that is, the pressure distribution changes between the stationary state and the rotating state. As a result, the gas holding force distribution for the wafer fluctuates, which may adversely affect the flatness of the wafer.

The present disclosure provides a technology for holding a substrate with a high degree of flatness and high precision.

### Solution to Problem

A substrate holding apparatus of the present disclosure includes: a rotary stage; and a clamp part that supports an edge of a substrate which is an object to be rotated by the rotary stage in a planar direction of the substrate, in which the rotary stage is provided with: a plurality of gas supply openings that supply a gas toward the substrate; and one or more gas exhaust openings that are provided to each of the plurality of gas supply openings so as to surround peripheries of the gas supply openings.

Further features related to the present disclosure will become apparent from the description of the present specification and the accompanying drawings. In addition, the aspects of the present disclosure are achieved and realized by elements, combinations of various elements, the following detailed description, and aspects of the appended claims.

The description of the present specification is merely exemplary, and does not limit the scope of claims or application examples of the present disclosure in any sense.

### Advantageous Effects of Invention

With the substrate holding apparatus of the present disclosure, the substrate can be held with high flatness and high accuracy. Problems, configurations, and effects other than those described above will be clarified by the following description of embodiments.

### BRIEF DESCRIPTION OF DRAWINGS

FIG. 1 is a schematic diagram illustrating a wafer processing system according to a first embodiment.

FIG. 2 is a perspective view illustrating a wafer chuck of the first embodiment.

FIG. 3A is a plan view of an air bearing pad, and FIG. 3B is a cross-sectional view taken along line C-C of FIG. 3A.

FIG. 4A is a plan view showing an aspect of an air flow in the air bearing pad, and FIG. 4B is a cross-sectional view taken along line D-D of FIG. 4A (lower part) and a view showing a pressure distribution (upper part).

FIG. 5 is a cross-sectional view taken along line B-B of FIG. 2, and illustrates the operation of each component of a clamp part before holding a wafer in the in-plane direction.

FIG. 6 is a cross-sectional view taken along line B-B of FIG. 2, and illustrates the operation of each component of the clamp part when the wafer is held by a holding claw.

FIG. 7 is a cross-sectional perspective view taken along line A-A of FIG. 2.

FIG. 8 is a flowchart illustrating an operation of loading the wafer into the wafer chuck.

FIG. 9 is a cross-sectional view illustrating a state of the wafer chuck in step S4 of FIG. 8.

FIG. 10 is a cross-sectional view illustrating a state of the wafer chuck in step S7 of FIG. 8.

FIG. 11 is a cross-sectional view illustrating a configuration of a wafer chuck according to Modification 1.

FIG. 12A is a plan view illustrating an air bearing pad according to Modification 2, and FIG. 12B is a cross-sectional view taken along line E-E of FIG. 12A.

FIG. 13A is a plan view illustrating an air bearing pad according to Modification 3, and FIG. 13B is a cross-sectional view taken along line F-F of FIG. 13A.

FIG. 14 is a cross-sectional view illustrating a configuration of a wafer chuck according to a second embodiment.

FIG. 15 is a cross-sectional view illustrating a structure of a wafer chuck according to a third embodiment.

### DESCRIPTION OF EMBODIMENTS

In each embodiment, a substrate held by a substrate holding apparatus will be described as a wafer, but the substrate of the present disclosure is not limited to a wafer, and may be any type as long as the substrate has a flat plate shape, such as a glass substrate, a liquid crystal panel, an electronic circuit board, an optical disk, or a magnetic disk.

In the present disclosure, a vertical direction of a wafer surface is referred to as an “out-of-plane direction” or a “vertical direction”, and a direction along the wafer surface is referred to as an “in-plane direction” or a “horizontal direction”. In addition, a member on which a rotary stage and the substrate (wafer) holding mechanism are mounted is referred to as a wafer chuck (substrate holding apparatus).

### First Embodiment

<Configuration Example of Wafer Processing System>

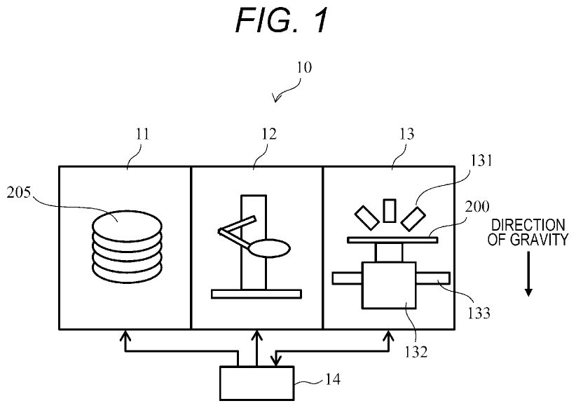

FIG. 1 is a schematic diagram illustrating a wafer processing system 10 according to a first embodiment. As illustrated in FIG. 1, the wafer processing system 10 (substrate processing apparatus) includes an introduction unit 11, a conveyance device 12, an inspection chamber 13, and a control device 14.

The wafer 205 housed in a wafer cassette (not illustrated) is loaded into the introduction unit 11. The conveyance device 12 takes out the wafers 205 from the wafer cassette loaded in the introduction unit 11, and conveys the wafers one by one to the inspection chamber 13 (for example, a foreign matter inspection device).

The inspection chamber 13 includes a wafer chuck 200, an optical measurement unit 131, a motor 132, and a linear motion moving unit 133. The wafer 205 conveyed to the inspection chamber 13 is arranged on the wafer chuck 200 and held with high flatness by the wafer chuck 200. A method of holding the wafer 205 by the wafer chuck 200 will be described later. The optical measurement unit 131 is fixed at a position above the wafer chuck 200, and optically measures the position and size of the foreign matter on the wafer 205. As described above, the optical measurement unit 131, the wafer 205, and the wafer chuck 200 are arranged in this order from the top in the direction of gravity. The measurement result by the optical measurement unit 131 is transmitted to the control device 14.

The wafer chuck 200 is rotationally supported by the motor 132 so that foreign matter can be measured while the wafer 205 is rotationally moved. The linear motion moving unit 133 moves the motor 132 in a vertical direction to the rotation axis of the motor 132. With such a configuration, the control device 14 can map the size, position, and the like of the foreign matter on the entire surface of the wafer 205 and record the size, position, and the like as foreign matter data of the wafer 205. The wafer 205 for which the measurement is completed is transferred again from the wafer chuck 200 by the conveyance device 12 and returned to the wafer cassette of the introduction unit 11. The above process is repeated to inspect all the wafers 205 in the cassette for foreign matters.

The control device 14 controls operations of the conveyance device 12, the wafer chuck 200, the motor 132, and the linear motion moving unit 133. The control device 14 can be configured with, for example, a computer terminal such as a personal computer, a smartphone, or a tablet.

The wafer processing system 10 is installed in a space where cleanliness is maintained so as not to allow foreign matter to adhere to the wafer 205.

<Configuration Example of Wafer Chuck>

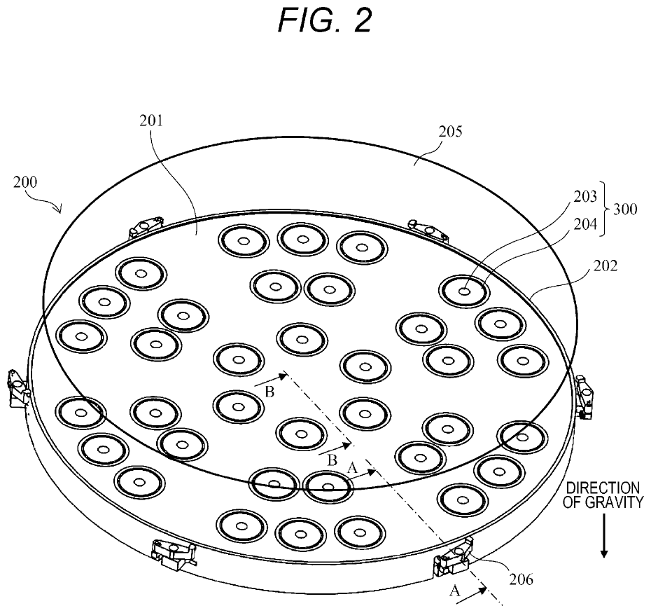

FIG. 2 is a perspective view illustrating the wafer chuck 200, and the wafer 205 is illustrated as a transparent view separated from the wafer chuck 200. As illustrated in FIG. 2, the wafer chuck 200 includes a rotary stage 201, a wafer support unit 202, a plurality of air bearing pads 300, and a plurality of clamp parts 206.

The rotary stage 201 is connected to the motor 132 so as to rotate about the center as a rotation axis. The wafer support unit 202 is a protrusion provided along the outer periphery of the upper surface of the rotary stage 201, and supports the edge portion of the wafer 205 from the lower surface of the wafer 205.

The air bearing pad 300 is provided on the upper surface side of the rotary stage 201. The air bearing pad 300 has a gas supply opening 203 and a gas exhaust opening 204, and holds the out-of-plane direction of the wafer 205 using a gas force. The arrangement pattern of the air bearing pads 300 when the wafer chuck 200 is viewed in a plan view from above may be point symmetric with the rotation center of the rotary stage 201 as a symmetric point, or may be random arrangement. By making the arrangement pattern of the air bearing pads 300 point symmetric, it is easy to control the vibration of the wafer 205.

The gas supply opening 203 is provided at the center of the air bearing pad 300. The gas exhaust opening 204 has an annular shape centered on the gas supply opening 203 in a plan view, and is arranged so as to surround the gas supply opening 203. Therefore, the distance between the gas supply opening 203 and the gas exhaust opening 204 is constant. As described above, the gas supply opening 203 forms a pair of supply and exhaust ports including one gas exhaust opening 204 for one gas supply opening 203.

Here, the gas supply opening 203 of a certain (first) air bearing pad 300 is defined as a first gas supply opening, and the gas exhaust opening 204 arranged around the gas supply opening is defined as a first gas exhaust opening. Similarly, the gas supply opening 203 of another (second) air bearing pad 300 is defined as a second gas supply opening, and the gas exhaust opening 204 arranged around the gas supply opening is defined as a second gas exhaust opening. In addition, a circle centered on the first gas supply opening and having a radius equal to a distance between the first gas supply opening and the first gas exhaust opening is defined as a first virtual circumference. Similarly, a circle centered the second gas supply opening and having a radius equal to a distance between the second gas supply opening and the second gas exhaust opening is defined as a second virtual circumference. At this time, a part of the first virtual circumference and a part of the second virtual circumference exist between the first gas supply opening and the second gas supply opening. In other words, in the present embodiment, the gas exhaust opening 204 is positioned between the respective gas supply openings 203 in any two air bearing pads 300.

In one air bearing pad 300, conditions of a structure and pressure are given such that the amount of gas supplied to the gas supply opening 203 and the amount of gas exhausted from the gas exhaust opening 204 are equal. As a result, the flow path is completed for each air bearing pad 300, and the air flow does not interfere with the other air bearing pads 300.

The material of the rotary stage 201 and the material of the air bearing pad 300 may be the same or different.

The clamp part 206 holds the wafer 205 by pressing the edge of the wafer 205 in the in-plane direction. In the example illustrated in FIG. 2, six clamp parts 206 are provided at equal intervals, but the number is not limited to six.

<Holding Structure in Out-of-Plane Direction>

The holding structure in the out-of-plane direction of the wafer 205 will be described.

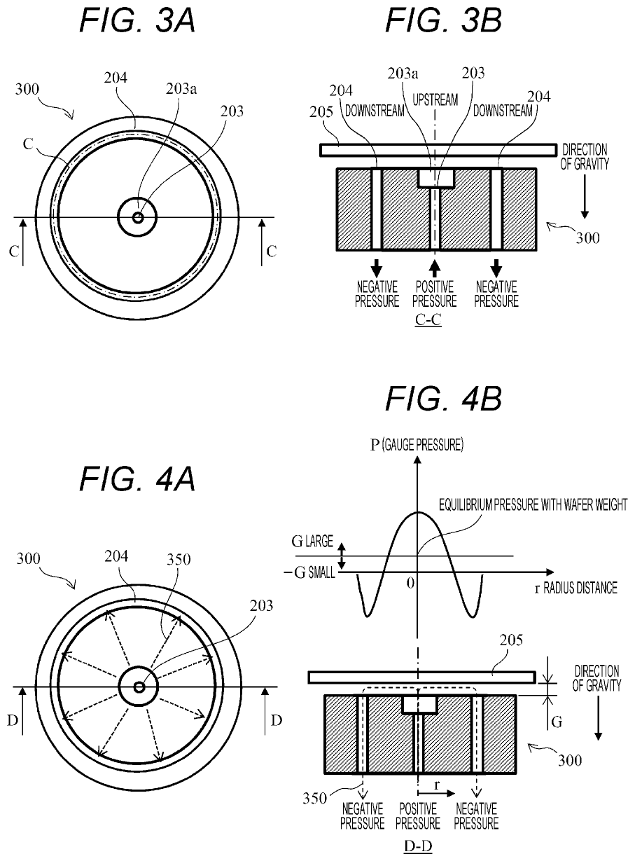

FIG. 3A is a plan view of the air bearing pad 300. FIG. 3B is a cross-sectional view taken along line C-C of FIG. 3A.

As shown in FIGS. 3A and 3B, in the flow path with the gas supply opening 203 as the upstream and the gas exhaust opening 204 as the downstream, a space 203a having a radius larger than the radius of the gas exhaust opening 204 is provided in the gas supply opening 203 as the upstream. That is, the upper end of the gas supply opening 203 is provided at a position lower than the upper end of the gas exhaust opening 204. Downstream of the space 203a, a clearance closest to the wafer 205 is assumed. The gas is exhausted by the gas exhaust opening 204 at the most downstream.

As described above, for each air bearing pad 300, it is possible to define a virtual circumference C centered on the gas supply opening 203 and having a radius that is the distance between the gas supply opening 203 and the gas exhaust opening 204. The distance between the gas supply opening 203 and the gas exhaust opening 204 is the distance between the center of the gas supply opening 203 and the center in the width direction of the annular ring formed by the gas exhaust opening 204.

As illustrated in FIG. 3B, gas is supplied to the gas supply opening 203 by application of a positive pressure, and a negative pressure is applied to the gas exhaust opening 204. A gas supply source (not illustrated) that supplies gas by applying a positive pressure is connected to a lower end of the gas supply opening 203, and a gas exhaust source (not illustrated) that exhausts gas by applying a negative pressure is connected to a lower end of the gas exhaust opening 204.

FIG. 4A is a plan view showing an aspect of an air flow in the air bearing pad 300. FIG. 4B is a cross-sectional view taken along line D-D of FIG. 4A (lower part) and a view illustrating a pressure distribution in the air bearing pad 300 (upper part). In FIGS. 4A and 4B, gas streamlines 350 are indicated by dotted lines.

As illustrated in FIGS. 4A and 4B, by supplying gas from the gas supply opening 203 to the space 203a with the wafer 205 at a pressure equal to or higher than the atmospheric pressure, a force for pushing up the wafer 205 can be applied. The space 203a functions as a buffer space because an area facing the wafer 205 and a space volume can be secured, so that a region facing the wafer 205 has an even pressure distribution. Therefore, even if the clearance between the wafer 205 and the gas supply opening 203 fluctuates, the fluctuation of the pressure can be reduced as much as possible.

The gas overflowing the space 203a flows in the 360° direction. Since the gas flowing out of the space 203a passes through a region narrower than the gap between the wafer 205 and the space 203a, the passing speed is increased. As a result, a negative pressure region lower than the atmospheric pressure is generated in the region between the space 203a and the gas exhaust opening 204, and a force for pulling the wafer 205 toward the wafer chuck 200 is generated.

Since the gas flowing to the gas exhaust opening 204 is exhausted here, the region of the pressure acting on the wafer 205 is completed at the gas exhaust opening 204.

This pressure action is drawn as a pressure distribution from the gas supply opening 203 to the gas exhaust opening 204 as illustrated in the upper part of FIG. 4B. Since the surface of the air bearing pad 300 facing the wafer 205 has a pressure distribution in which a positive pressure region and a negative pressure region exist, a pressing force and a tensile force are generated with respect to the wafer 205. As a result, a gap G that is balanced with the wafer weight is generated between the wafer 205 and the air bearing pad 300. In the upper graph of FIG. 4B, the gap G indicates a force acting on the wafer 205 when the pressure curve is integrated in the plane of the air bearing pad 300, that is, a distance at which a value on the positive pressure side (repulsive force to the wafer 205) and a value on the negative pressure side (attractive force to the wafer 205) are equal with the equilibrium pressure point as a boundary. In a case where the distance between the wafer 205 and the air bearing pad 300 deviates from the balanced gap G, that is, for example, in a case where the wafer 205 approaches the air bearing pad 300 side, a repulsive force acts because the positive pressure with respect to the wafer 205 is superior. On the other hand, when the distance is increased, the attractive force acts because the tensile force is superior. This action generates holding rigidity for the wafer 205. Thus, if the ratio between the supply pressure of the gas supply opening 203 and the exhaust pressure of the gas exhaust opening 204 are not changed, and the values of the both are increased, the holding rigidity for the wafer 205 can be increased.

The wafer holding rigidity of the wafer chuck 200 may be any rigidity that can hold the weight of one wafer 205. By arranging a plurality of air bearing pads 300 on the wafer chuck 200, the holding rigidity of the air bearing pads 300 can be shared by the number of air bearing pads arranged on the wafer chuck 200, so that design with a margin is possible. The gap between the wafer 205 and the wafer chuck 200 is controlled by the above action, and the wafer 205 can be held with high flatness in the out-of-plane direction.

<Holding Structure in In-Plane Direction>

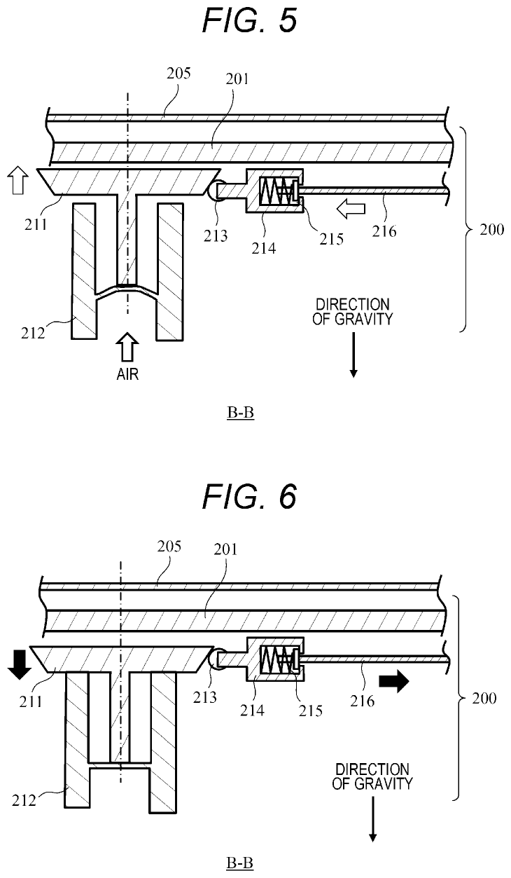

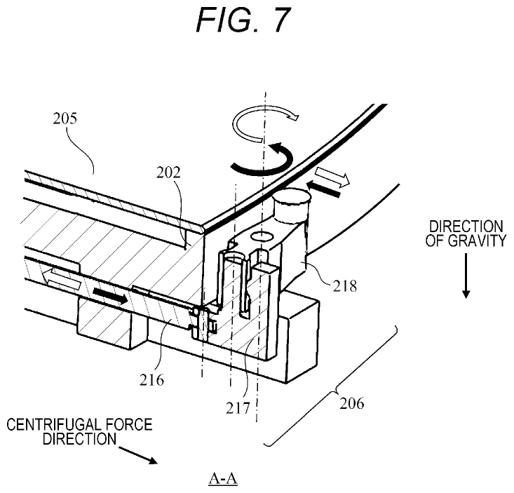

FIG. 5 is a cross-sectional view taken along line B-B of FIG. 2, and illustrates the operation of each component of the clamp part 206 before the wafer 205 is held in the in-plane direction. As illustrated in FIG. 5, the clamp part 206 is built in the wafer chuck 200, and includes a cam 211, an air cylinder 212, a bearing 213, a bearing holding unit 214, a compression spring 215, and a rod 216. As will be described later with reference to FIG. 7, a link that allows displacement in the circumferential direction is connected to the rod 216, and a holding claw (pressing portion) that comes into contact with the wafer 205 is mounted on the link.

The air cylinder 212 is arranged on the central axis below the rotary stage 201 which is a base of the wafer chuck 200, and the cam 211 is attached to the air cylinder 212 in a vertically movable manner. Air is supplied to the air cylinder 212 by a pump (not illustrated) or the like. The supply of air to the air cylinder 212 is controlled by the control device 14 described above. The bearing 213 is held by the bearing holding unit 214 to come into contact with the cam 211 and converts the movement of the cam 211 in the vertical direction into the radial direction of the rotary stage 201. The rod 216 is movable relative to the bearing holding unit 214 in the radial direction. The compression spring 215 radially supports the bearing holding unit 214 and the rod 216.

As indicated by a white arrow in FIG. 5, when the air cylinder 212 operates and the cam 211 moves upward, the rod 216 moves radially inward.

FIG. 6 is a cross-sectional view taken along line B-B in FIG. 2 and illustrates the operation of each component of the clamp part 206 when the wafer 205 is held by a holding claw 218 after the wafer 205 is mounted on the rotary stage 201. As indicated by a black arrow in FIG. 6, when the operation of the air cylinder 212 is stopped and the cam 211 moves downward, the rod 216 moves radially outward.

FIG. 7 is a cross-sectional perspective view taken along line A-A in FIG. 2, and illustrates the periphery of the holding claw 218. As illustrated in FIG. 7, the rod 216 extends to an outer peripheral end (radial end) of the rotary stage 201, and a link 217 is connected to the end of the rod 216. The link 217 is rotatable with the vertical direction (the out-of-plane direction of the wafer 205) as the rotation axis direction. The link 217 is provided with the holding claw 218 supported in a rotatable manner in an in-plane direction of the wafer 205 with a vertical direction as a rotation axis direction.

The surface of the holding claw 218 in contact with the wafer 205 is a surface perpendicular to the surface of the wafer 205 and is an upright cylindrical surface in the present embodiment. Of course, even if the surface of the holding claw 218 in contact with the wafer 205 is a flat surface, the wafer 205 can be held in the horizontal direction.

The mechanisms excluding the air cylinder 212 and the cam 211 of the clamp part 206 are arranged symmetrically with respect to the central axis of the wafer chuck 200. The number of mechanisms such as the holding claws 218 can be determined in consideration of the generated holding force of each mechanism and the necessary holding force of the wafer 205.

The operation of the clamp part 206 will be described. The control device 14 (FIG. 1) supplies the air to the air cylinder 212 after the wafer 205 is brought into the inspection chamber 13 by the conveyance device 12. As indicated by the white arrow in FIG. 5, the cam 211 moves upward and the rod 216 moves radially inward. Since the holding claw 218 is attached at a position symmetrical to the link 217 with respect to the rotation axis, the link 217 is displaced radially inward following the movement of the rod 216, and the holding claw 218 is displaced radially outward as indicated by the white arrow in FIG. 7. As a result, since the position of the holding claw 218 moves to the outside of the outer peripheral end of the wafer 205, the wafer chuck 200 is ready to receive the wafer 205.

Thereafter, the conveyance device 12 is arranged on the rotary stage 201, and places the wafer 205 on the wafer support unit 202 having an annular shape that holds the outer peripheral portion of the lower surface of the wafer 205 in the vertical direction.

The control device 14 (FIG. 1) stops air supply to the air cylinder 212 after the conveyance device 12 is retracted. As a result, as indicated by the black arrow in FIG. 6, the cam 211 moves downward and the rod 216 moves radially outward, and as indicated by a black arrow in FIG. 7, the holding claw 218 horizontally rotates and abuts on the outer peripheral end of the wafer 205 to generate holding force. During this time, the bearing holding unit 214, the rod 216, and the compression spring 215 connecting the bearing holding unit 214 and the rod 216 move integrally to the outer peripheral side in the direction of the black arrows in FIGS. 6 and 7 until the holding claw 218 abuts on the outer peripheral end of the wafer 205.

Thereafter, with the stop of the rod 216, the bearing holding unit 214 continues to move radially outward until the movement of the cam 211 is completed. At this time, the compression spring 215 contracts due to the contraction of the relative distance between the bearing holding unit 214 and the rod 216. As a result, the compression spring 215 generates an axial force due to the reaction force, and this force is transmitted to the holding claw 218. As a result, the spring force of the compression spring 215 becomes the holding force of the holding claw 218 in the in-plane direction of the wafer 205. The spring force of compression spring 215 is a ratio of a distance from the rotation center of the holding claw 218 (supporting point) to the joint shaft (force point) of the link 217 and a distance from the rotation center (action point) of the holding claw 218.

Next, the holding force of the clamp part 206 will be described. Functions required for holding the wafer 205 by the clamp part 206 are mainly an alignment function in a state of mounting the wafer 205, a slip prevention function in a rotation start-up state, and a function against a centrifugal force caused by eccentricity of the wafer 205 in a steady rotating state. The alignment function at the time of mounting the wafer 205 is covered by a static holding force. This is a holding force generated by the compression spring 215 of the clamp part 206. Regarding the prevention of slip and the centrifugal force of the wafer 205, since the centrifugal force generated by each component of the clamp part 206 is added to the holding force, the centrifugal force is considered. In the rotation start-up state, a holding force equal to or larger than an inertial force for stopping the wafer 205 is required. In the steady rotating state, a holding force equal to or larger than a centrifugal force obtained by integrating the eccentricity amount, the mass, and the rotation speed of the wafer 205 is required. The holding force against these forces can be adjusted by the shape and mass of components such as the bearing 213, the bearing holding unit 214, the rod 216, and the link 217.

<Wafer Loading Operation>

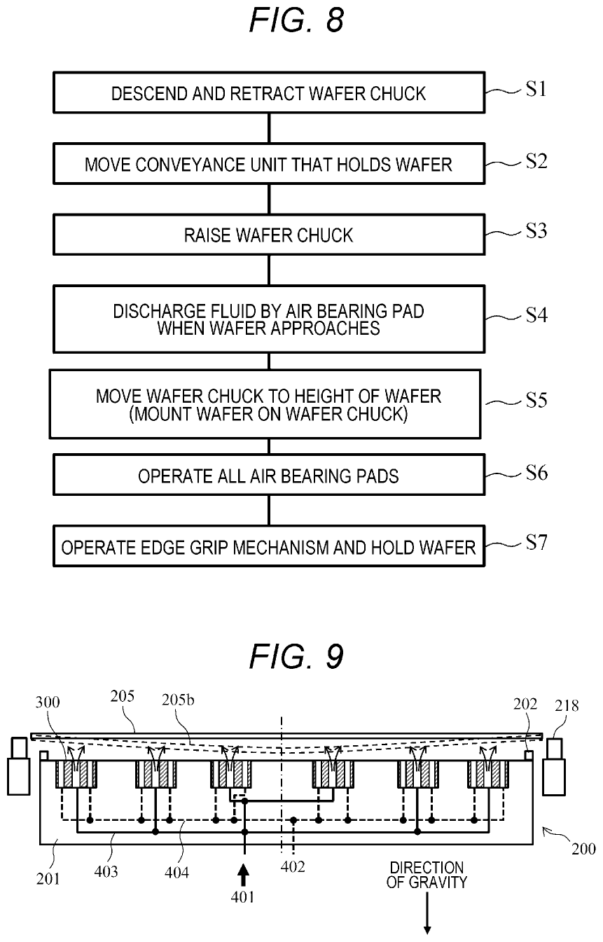

FIG. 8 is a flowchart illustrating an operation of loading the wafer 205 into the wafer chuck 200. Each operation in FIG. 8 is executed by driving each device by the control device 14 of the wafer processing system 10 illustrated in FIG. 1, but each device of the wafer processing system 10 will be described below as a main body of the operation.

In step S1, the wafer chuck 200 descends and retracts.

In step S2, the conveyance device 12 conveys the wafer 205 until the center of the rotary stage 201 of the wafer chuck 200 in the inspection chamber 13 coincides with the center of the wafer 205.

In step S3, the wafer chuck 200 is raised to a height at which the wafer 205 can be loaded.

FIG. 9 is a cross-sectional view illustrating a state of the wafer chuck 200 in step S4 of FIG. 8. As illustrated in FIG. 9, the rotary stage 201 is provided with a gas supply source 401 connected to each of the gas supply openings 203 of all the air bearing pads 300 by a pipe 403 and a gas exhaust source 402 connected to each of the gas exhaust openings 204 by a pipe 404. The gas supply source 401 and the gas exhaust source 402 can be configured with, for example, a pump. The driving of the gas supply source 401 and the gas exhaust source 402 is controlled by the above-described control device 14 (FIG. 1).

In step S4, the control device 14 drives the gas supply source 401 to supply positive pressure gas to the gas supply openings 203 of all the air bearing pads 300.

Since the outer peripheral portion of the wafer 205 is supported by the conveyance device 12, the wafer has deformation due to self-weight sinking in which the central portion bends in the direction of gravity during conveyance or when moving onto the wafer chuck 200 (wafer 205b). When the plurality of air bearing pads 300 on the wafer chuck 200 are formed on the same plane, it is likely that the central portion of the wafer 205 comes into contact with the wafer chuck 200 due to self-weight sinking of the wafer 205. In order to avoid the contact, the gas is supplied from the gas supply source 401, and the positive pressure gas is discharged from the air bearing pad 300. As a result, since the deformation of the wafer 205 due to self-weight sinking is corrected, it is possible to avoid the contact of the wafer 205 with the wafer chuck 200.

Returning to FIG. 8, in step S5, the wafer chuck 200 ascends until the wafer 205 is placed on the wafer support unit 202.

In step S6, the control device 14 drives the gas supply source 401 and the gas exhaust source 402 to hold the lower surface of the wafer 205 in the out-of-plane direction.

In step S7, the control device 14 drives the clamp part 206 to hold the wafer 205 in the in-plane direction while centering the wafer 205 by the holding claw 218, and the loading of the wafer 205 into the wafer chuck 200 is completed.

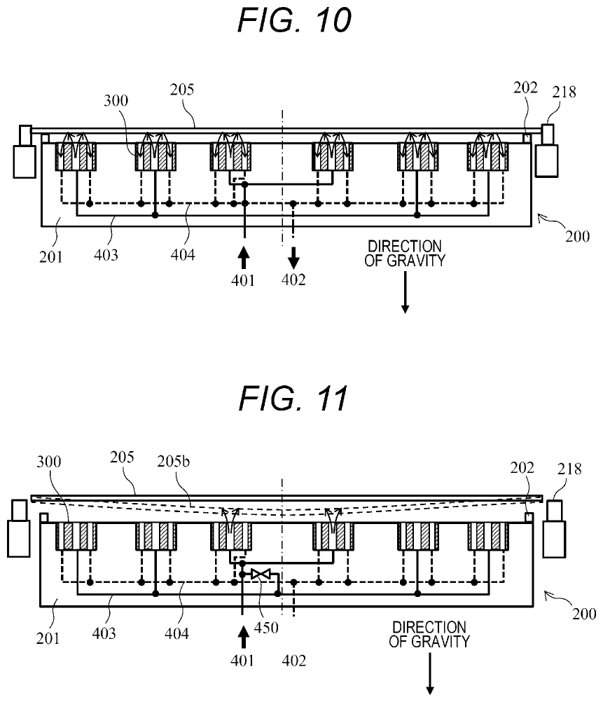

FIG. 10 is a cross-sectional view illustrating a state of the wafer chuck 200 in step S7. As illustrated in FIG. 10, the wafer 205 is held in the out-of-plane direction by the air bearing pad 300 and held in the in-plane direction by the holding claw 218, so that the wafer is held by the wafer chuck 200 with high flatness.

The amount and coordinates of the surface dust of the wafer 205 held as described above are inspected by the optical measurement unit 131 (FIG. 1).

### Modification 1

FIG. 11 is a cross-sectional view illustrating a configuration of the wafer chuck 200 according to Modification 1. As illustrated in FIG. 11, the pipe 403 branches so as to be able to supply the gas only to the air bearing pad 300 positioned at the central portion of the rotary stage 201, and is provided with a valve 450 (switching mechanism) that controls supply and interruption of gas to the air bearing pad 300 positioned at the peripheral portion. The opening and closing of the valve 450 can be controlled by the control device 14.

In step S4 described above, by closing the valve 450 and supplying the positive pressure gas only to the air bearing pad 300 positioned at the central portion of the rotary stage 201, the self-weight sinking of the wafer 205 can be corrected more efficiently. In step S6, the valve 450 is opened. In FIG. 11, the valve 450 is built in the wafer chuck 200, but of course, the effect is similar even if the valve 450 is installed outside the wafer chuck 200.

### Modification 2

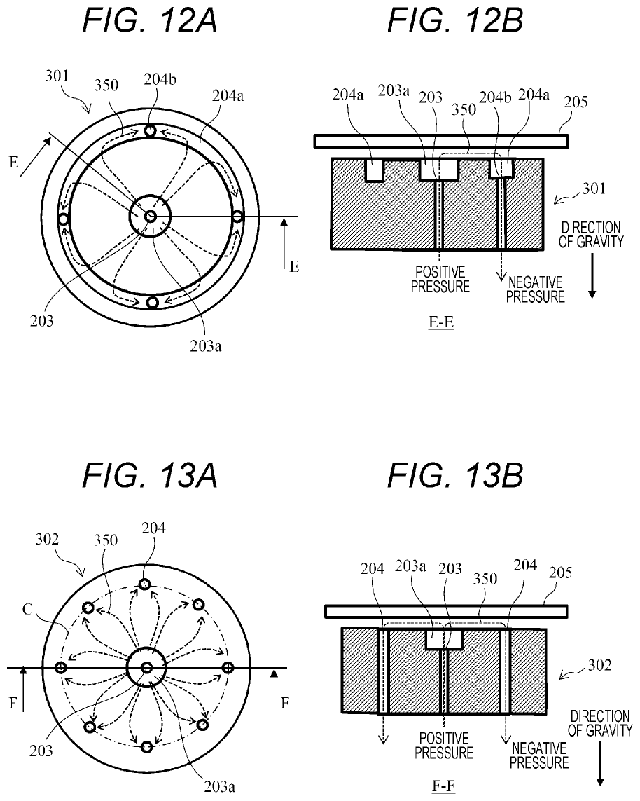

FIG. 12A is a plan view illustrating an air bearing pad 301 according to Modification 2. FIG. 12B is a cross-sectional view taken along line E-E of FIG. 12A.

As illustrated in FIGS. 12A and 12B, a groove 204a in an annular shape is provided on the upper surface of the air bearing pad 301 so as to surround the gas supply opening 203, and a plurality of gas exhaust openings 204b communicating with the groove 204a are provided. The number of the gas exhaust openings 204 can be changed according to the arrangement pattern of the air bearing pad 301. In the example illustrated in FIG. 12A, four gas exhaust openings 204b are provided every 90°. The distance between the center of the gas supply opening 203 and the center of each gas exhaust opening 204b in a plan view of the air bearing pad 301 is the same.

With such a structure, the inside of the groove 204a becomes a negative pressure region, and all the gas supplied from the gas supply opening 203 can be exhausted from the gas exhaust openings 204b formed in the groove 204a. As described above, the flow path is completed for each air bearing pad 301, and the air flow does not interfere with other air bearing pads 301.

The depth of the groove 204a is not limited, but may be, for example, equal to the depth of the space 203a or deeper than the space 203a. By setting the depth of the groove 204a to be equal to or greater than the depth of the space 203a, the gas can be exhausted more efficiently.

Also in Modification 2, similarly to the first embodiment, the gas supply opening 203 of a certain (first) air bearing pad 301 is set as the first gas supply opening, and the gas exhaust opening 204b arranged around the gas supply opening is set as the first gas exhaust opening. Similarly, the gas supply opening 203 of another (second) air bearing pad 301 is defined as the second gas supply opening, and the gas exhaust opening 204b arranged around the gas supply opening is defined as the second gas exhaust opening. In addition, a circle centered on the first gas supply opening and having a radius equal to a distance between the first gas supply opening and the first gas exhaust opening is defined as a first virtual circumference. Similarly, a circle centered the second gas supply opening and having a radius equal to a distance between the second gas supply opening and the second gas exhaust opening is defined as a second virtual circumference. At this time, a part of the first virtual circumference and a part of the second virtual circumference exist between the first gas supply opening and the second gas supply opening.

### Modification 3

FIG. 13A is a plan view illustrating an air bearing pad 302 according to Modification 3. FIG. 13B is a cross-sectional view taken along line F-F of FIG. 13A.

As illustrated in FIGS. 13A and 13B, the air bearing pad 302 does not include the groove 204a described above but is provided with the plurality of gas exhaust openings 204c so as to surround the gas supply opening 203. In the example illustrated in FIG. 13A, eight gas exhaust openings 204c are provided every 45° on the virtual circumference C.

Even with such a structure, without releasing the gas supplied from the gas supply opening 203, all the gas can be collected at the gas exhaust openings 204c and exhausted. As described above, the flow path is completed for each air bearing pad 302 and the air flow does not interfere with other air bearing pads 302.

### Technical Effects

As described above, in the wafer chuck 200 of the first embodiment, the plurality of gas supply openings 203 are provided in the rotary stage 201, and one or more gas exhaust openings 204 are provided so as to surround the periphery of each of the plurality of gas supply openings 203. As a result, since the flow path of the gas is locally formed, the fluctuation of the distribution of the holding pressure in the out-of-plane direction of the wafer 205 can be minimized even if the centrifugal force acts. As a result, the flatness of the wafer 205 can be maintained with high accuracy.

The mechanical restraint of the wafer 205 is only the pressing in the in-plane direction using the holding claw 218 of the clamp part 206, the factor causing the deformation of the wafer 205 is eliminated, and thus high flatness can be achieved.

As described above, since the wafer chuck 200 can hold the wafer 205 with high flatness, foreign matters can be detected with high accuracy when the wafer chuck is mounted on the foreign matter inspection device.

### Second Embodiment

In the first embodiment described above, an example in which one gas supply source and one gas exhaust source are provided for all the air bearing pads 300 is described, but the number of gas supply sources and gas exhaust sources may be plural. Therefore, in a second embodiment, an example in which the plurality of gas supply sources and the plurality of gas exhaust sources are provided is suggested.

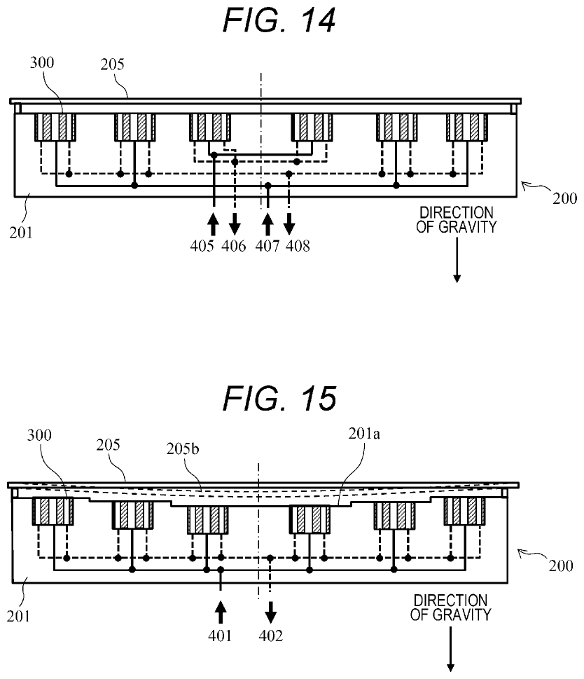

FIG. 14 is a cross-sectional view illustrating a configuration of the wafer chuck 200 according to the second embodiment. As illustrated in FIG. 14, a first gas supply source 405 and a first gas exhaust source 406 are connected to the air bearing pads 300 positioned in the central portion of the rotary stage 201, and a second gas supply source 407 and a second gas exhaust source 408 are connected to the air bearing pads 300 positioned in the peripheral portion of the rotary stage 201.

The first gas supply source 405 and the second gas supply source 407 can supply gases having different pressures (supply pressures). The first gas exhaust source 406 and the second gas exhaust source 408 can exhaust gases at different pressures (exhaust pressures). By making the ratio between the supply pressure of the first gas supply source 405 and the exhaust pressure of the first gas exhaust source 406 and the ratio between the supply pressure of the second gas supply source 407 and the exhaust pressure of the second gas exhaust source 408 constant, the gap G between the air bearing pad 300 and the wafer 205 can be made constant. For example, by making the pressures (values of the supply pressure and the exhaust pressure) of the first gas supply source 405 and the first gas exhaust source 406 higher than the pressures (values of the supply pressure and the exhaust pressure) of the second gas supply source 407 and the second gas exhaust source 408 while maintaining the ratio of the supply pressure and the exhaust pressure, the holding force of the wafer 205 at high flatness can be strengthened against disturbance.

In the example illustrated in FIG. 14, the air bearing pads 300 positioned in the central portion and the air bearing pads 300 positioned in the peripheral portion can have different gas supply and exhaust pressures, but the connection destination of the first gas supply source 405 and the first gas exhaust source 406 and the connection destination of the second gas supply source 407 and the second gas exhaust source 408 can be arbitrarily changed.

In addition, the plurality of gas supply sources and the plurality of gas exhaust sources can be connected to one air bearing pad 300.

### Technical Effects

As described above, in the second embodiment, two sets (a plurality of sets) of the gas supply sources and the gas exhaust sources which are independently controlled are provided. As a result, the supply pressure and the exhaust pressure of the gas can be efficiently controlled according to the arrangement of the air bearing pad 300.

### Third Embodiment

In the first and second embodiments described above, the example in which the upper surface of the rotary stage 201 is flat is described, but the rotary stage 201 may have a shape in which the height is lower toward the central portion and is higher toward the outside in the radial direction according to the deformation shape due to the self-weight sinking of the wafer.

FIG. 15 is a cross-sectional view illustrating a structure of the wafer chuck 200 according to a third embodiment. As illustrated in FIG. 15, the upper surface of the rotary stage 201 is formed in a stepped structure in which the height is lower toward the central portion along the shape (wafer 205b) when the wafer 205 is deformed by the self-weight sinking. In the example illustrated in FIG. 15, the steps are three steps, but may be two steps or more. Further, the shape of the rotary stage 201 may be a structure in which the height changes continuously instead of the stepped structure.

By connecting the plurality of sets of the gas supply sources and the gas exhaust sources to the rotary stage 201 of the present embodiment as in the second embodiment, the value of the supply pressure of the gas supplied to the air bearing pad 300 in the central portion can be made larger than the value of the supply pressure of the gas supplied to the air bearing pad 300 in the peripheral portion while maintaining the ratio of the supply pressure and the exhaust pressure, and the value of the exhaust pressure of the gas exhausted from the air bearing pad 300 in the central portion can be made larger than the value of the exhaust pressure of the gas exhausted from the air bearing pad 300 in the peripheral portion.

### Technical Effects

As described above, in the third embodiment, the rotary stage 201 has a shape in which the height is lower toward the central portion and is higher toward the outside in the radial direction. As a result, when the wafer chuck 200 is raised to bring the wafer 205 and the rotary stage 201 close to each other in steps S3 to S4 described above, it is possible to avoid contact between the wafer 205 and the rotary stage 201 without supplying gas from the gas supply source 401. Therefore, the energy required for the operation of loading the wafer 205 into the wafer chuck 200 can be reduced.

### Modification

The present disclosure is not limited to the above-described embodiments, and includes various modifications. For example, the above-described embodiments have been described in detail in order to describe the present disclosure in an easy-to-understand manner and are not required to necessarily have all the described configurations. Further, a part of one embodiment can be replaced with a configuration of another embodiment. Further, a part of one embodiment can be added to a configuration of another embodiment. In addition, for a part of the configuration of each embodiment, a part of the configuration of another embodiment can be added, deleted, or replaced.

As an example of a modification, for example, in order to secure high flatness of the wafer, a desired structure and performance of the air bearing pad can be freely selected according to a position such as a radius to be mounted on the rotary stage.

### REFERENCE SIGNS LIST

10 wafer processing system
11 introduction unit
12 conveyance device
13 inspection chamber
14 control device
131 optical measurement unit
132 motor
133 linear motion moving unit
200 wafer chuck
201 rotary stage
202 wafer support unit
203 gas supply opening
203a space
204 gas exhaust opening
204a groove
205 wafer
206 clamp part
211 cam
212 air cylinder
213 bearing
214 bearing holding unit
215 compression spring
216 rod
217 link
218 holding claw
300 to 302 air bearing pad
350 gas streamline
401 gas supply source
402 gas exhaust source
403 pipe
404 pipe
405 first gas supply source
406 first gas exhaust source
407 second gas supply source
408 second gas exhaust source
450 valve

1. A substrate holding apparatus comprising:
a rotary stage; and
a clamp part that supports an edge of a substrate which is an object to be rotated by the rotary stage in a planar direction of the substrate,
wherein the rotary stage is provided with:
a plurality of gas supply openings that supply a gas toward the substrate; and
one or more gas exhaust openings that are provided to each of the plurality of gas supply openings so as to surround peripheries of the gas supply openings.

2. The substrate holding apparatus according to claim 1,
wherein a first gas exhaust opening is provided around a first gas supply opening among the plurality of gas supply openings, and a first distance between the first gas supply opening and the first gas exhaust opening is constant,
a second gas exhaust opening is provided around a second gas supply opening among the plurality of gas supply openings, and a second distance between the second gas supply opening and the second gas exhaust opening is constant, and
when a circle that is centered on the first gas supply opening and has a radius of the first distance is defined as a first virtual circumference and a circle that is centered on the second gas supply opening and has a radius of the second distance is defined as a second virtual circumference in a plan view of the rotary stage,
a part of the first virtual circumference and a part of the second virtual circumference exist between the first gas supply opening and the second gas supply opening.

3. The substrate holding apparatus according to claim 1, wherein one gas exhaust opening is provided to one gas supply opening among the plurality of gas supply openings, and the one gas exhaust opening annularly surrounds around the one gas supply opening.

4. The substrate holding apparatus according to claim 1, wherein an upper end of the gas supply opening is provided at a position lower than an upper end of the gas exhaust opening.

5. The substrate holding apparatus according to claim 1, further comprising:
a plurality of sets of gas supply sources and gas exhaust sources.

6. The substrate holding apparatus according to claim 5,
wherein, while the plurality of sets of gas supply sources and gas exhaust sources maintain a ratio between a value of a supply pressure of the gas in each of the plurality of gas supply openings and a value of an exhaust pressure of the gas in the one or more gas exhaust openings respectively corresponding to the plurality of gas supply openings,
the gas is supplied such that the value of the supply pressure of the gas supplied to the gas supply opening positioned in a central portion of the rotary stage among the plurality of gas supply openings is larger than the value of the supply pressure of the gas supplied to the gas supply opening positioned in a peripheral portion of the rotary stage, and
the gas is exhausted such that the value of the exhaust pressure of the gas exhausted from the one or more gas exhaust openings positioned in the central portion of the rotary stage is larger than the value of the exhaust pressure of the gas exhausted from the one or more gas exhaust openings positioned in the peripheral portion of the rotary stage.

7. The substrate holding apparatus according to claim 1, wherein an upper surface of the rotary stage is formed such that a height is higher toward an outer circumferential direction.

8. The substrate holding apparatus according to claim 1, wherein the plurality of gas exhaust openings are provided around the plurality of gas supply openings, respectively.

9. The substrate holding apparatus according to claim 1, further comprising:
a groove that is provided on an upper surface of the rotary stage and annularly surrounds around the one or more gas supply openings,
wherein the one or more gas exhaust openings communicate with the groove.

10. The substrate holding apparatus according to claim 1, further comprising:
a gas supply source that supplies the gas by applying a positive pressure to the plurality of gas supply openings; and
a switching mechanism that controls inflow and interruption of the gas from the gas supply source to the gas supply opening positioned in a peripheral portion of the rotary stage among the plurality of gas supply openings.

11. The substrate holding apparatus according to claim 1,
wherein the clamp part includes a pressing portion that presses the edge of the substrate in a planar direction of the substrate.

12. The substrate holding apparatus according to claim 1,
wherein an arrangement pattern of the plurality of gas supply openings when the rotary stage is viewed in a plan view is point symmetric with a rotation center point of the rotary stage as a symmetric point.

13. A substrate processing apparatus comprising:
the substrate holding apparatus according to claim 1; and
a measurement unit that measures a foreign matter on the substrate.
